(19) United States
(12) Patent Application Publication
(10) Pub. No.: US 2026/0033341 A1
(43) Pub. Date: Jan. 29, 2026

(54) PACKAGING STRUCTURE AND METHODS OF FORMING THE SAME

(71) Applicant: TAIWAN SEMICONDUCTOR MANUFACTURING COMPANY, LTD., Hsinchu (TW)

(72) Inventors: Yu-Fang TSENG, Hsinchu (TW); Yi Chen HO, Taichung (TW)

(21) Appl. No.: 18/948,834

(22) Filed: Nov. 15, 2024

Related U.S. Application Data
(60) Provisional application No. 63/675,853, filed on Jul. 26, 2024.

(51) Int. Cl. H01L 23/00; H01L 21/56; H01L 23/31; H01L 25/03

(52) U.S. Cl. CPC H01L 23/562; H01L 21/565; H01L 23/3121; H01L 24/24; H01L 25/03; H01L 24/16; H01L 2224/16141; H01L 2224/16227; H01L 2224/24145; H01L 2924/3511

(57) ABSTRACT

A packaging structure and methods of forming the same are described. In some embodiments, the structure includes a through via, a first semiconductor die disposed adjacent the through via, a stress relief layer disposed on side surfaces of the through via and side surfaces of the first semiconductor die, and a molding material disposed on the stress relief layer and between the through via and the first semiconductor die. Top surfaces of the through via, the semiconductor die, and the molding material are substantially coplanar.

### CROSS-REFERENCE TO RELATED APPLICATIONS

This application claims priority to U.S. Provisional Application Ser. No. 63/675,853 filed Jul. 26, 2024, which is incorporated by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for even smaller electronic devices has grown recently, there has grown a need for smaller and more creative packaging techniques of semiconductor dies.

An example of these packaging technologies is the integrated fan-out (InFO) package technology. In an InFO package, a die is embedded in a molding material, and a redistribution structure is disposed on the die. The die may be first bonded to a carrier substrate, and the redistribution structure is formed on the die over the carrier substrate. Warpage of the carrier substrate and the materials disposed thereon can occur as a result of coefficient of thermal expansion (CTE) mismatch between the carrier substrate and the molding material.

Therefore, an improved package structure is needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, and 7 are side views of various stages of manufacturing a packaging structure, in accordance with some embodiments.

FIGS. 8 and 9 are side views of various stages of manufacturing the packaging structure, in accordance with alternative embodiments.

FIGS. 10, 11, 12, and 13 are side views of various stages of manufacturing the packaging structure, in accordance with alternative embodiments.

FIG. 14 is a side view of one of various stages of manufacturing the packaging structure, in accordance with some embodiments.

FIGS. 15, 16, 17, 18, and 19 are side views of various stages of manufacturing the packaging structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

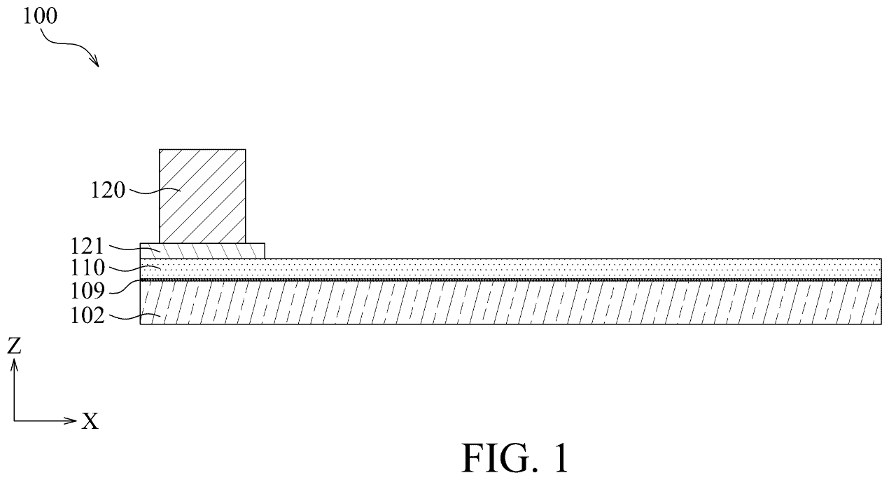

FIGS. 1-7 illustrate various stages of manufacturing a packaging structure 100 in accordance with various embodiments of this disclosure. It is understood that additional operations can be provided before, during, and after processes shown by FIGS. 1-7 and some of the operations described below can be replaced or eliminated, for additional embodiments of the method. The order of the operations/processes may be interchangeable.

FIGS. 1, 2, 3, 4, 5, 6, and 7 are side views of various stages of manufacturing the packaging structure 100, in accordance with some embodiments. As shown in FIG. 1, a buffer layer 110 is formed on a carrier 102. The buffer layer 110 is a dielectric layer, which may be a polymer layer. The polymer layer may include, for example, polyimide, polybenzoxazole (PBO), benzocyclobutene (BCB), an ajinomoto buildup film (ABF), a solder resist film (SR), or the like. The buffer layer 110 is a substantially planar layer having a substantially uniform thickness, in which the thickness may be greater than about 2 μm, and may be in a range from about 2 μm to about 40 μm. In some embodiments, top and bottom surfaces of the buffer layer 110 are also substantially planar. The carrier 102 may be a blank glass carrier, a blank ceramic carrier, or the like. In some embodiments, an adhesive layer 109 can be formed on the carrier 102, and the buffer layer 110 is formed on the adhesive layer 109. The adhesive layer 109 may be made of an adhesive, such as ultra-violet (UV) glue, light-to-heat conversion (LTHC) glue, or the like, although other types of adhesives may be used.

As shown in FIG. 1, a conductive feature 120 is formed over the buffer layer 110. In some embodiments, the conductive feature 120 may be formed on a seed layer 121. In some embodiments, the seed layer 121 is first formed on the buffer layer 110 as a blanket layer, for example, through physical vapor deposition (PVD) or metal foil laminating. The seed layer 121 may include copper, copper alloy, aluminum, titanium, titanium alloy, or combinations thereof. In some embodiments, the seed layer 121 includes a titanium layer and a copper layer over the titanium layer. In alternative embodiments, the seed layer 121 is a copper layer.

After the formation of the seed layer 121, a photoresist (not shown) is applied over the seed layer 121 and is then patterned. As a result, an opening (not shown) is formed in the photoresist, through which a portion of the seed layer is exposed. Next, the conductive feature 120 is formed in opening of the photoresist through plating, which may be electro plating or electro-less plating. The conductive feature 120 is plated on the exposed portion of the seed layer 121. The conductive feature 120 may include copper, aluminum, tungsten, nickel, solder, or alloys thereof. In some embodiments, the seed layer 121 and the conductive feature 120 include the same material, and the seed layer 121 may be merged with the conductive feature 120 with no distinguishable interface therebetween. In some embodiments, the conductive feature 120 is a through via, such as a through integrated fan-out via (TIV). After the plating of the conductive feature 120, the photoresist is removed. After the photoresist is removed, some portions of the seed layer 121 are exposed. Next, an etch process is performed to remove the exposed portions of seed layer 121, and the etch process may include an anisotropic etching. A portion of the seed layer 121 that is covered by the conductive feature 120, on the other hand, remains not etched. In some embodiments, as shown in FIG. 1, the width of the seed layer 121 along the X direction is greater than a width of the conductive feature 120 as a result of the anisotropic etch process. The seed layer 121 is omitted in the following figures for clarity.

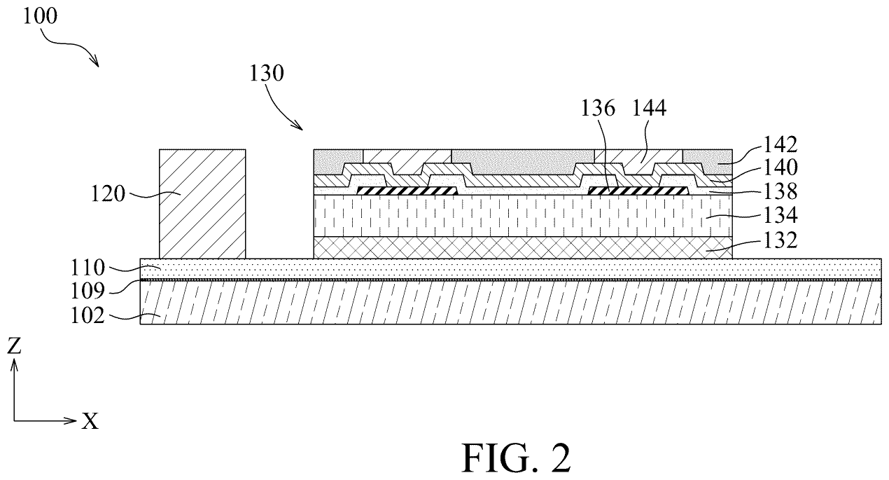

As shown in FIG. 2, a semiconductor die 130, such as a system-on-chip (SoC) die, is attached to the buffer layer 110. In some embodiments, the semiconductor die 130 is attached to the buffer layer 110 through a die-attach film (DAF) 132, which is an adhesive film pre-attached on the semiconductor die 130 before the semiconductor die 130 is placed on buffer layer 110. The semiconductor die 130 may include a semiconductor substrate 134 having a back surface (the surface facing down) in physical contact with the DAF 132. The semiconductor die 130 may include integrated circuit devices (such as active devices, which include transistors, resistors, capacitors, for example, not shown) at the front surface (the surface facing up) of the semiconductor substrate 134. Since the carrier 102 is at wafer level, although one semiconductor die 130 is illustrated, a plurality of semiconductor dies 130 is placed over the buffer layer 110, and the semiconductor dies 130 may be allocated as an array including a plurality of rows and a plurality of columns.

In some embodiments, an interconnect structure (not shown) is disposed over the integrated circuit devices. The interconnect structure may include a plurality of conductive features embedded in a dielectric material. The conductive features may be conductive lines and conductive vias. In some embodiments, passive devices, such as capacitors and/or resistors are also embedded in the dielectric material. The dielectric material may be any suitable dielectric material. In some embodiments, the dielectric material includes a plurality of intermetal dielectric (IMD) layers. As shown in FIG. 2, one or more contact pads 136 are disposed over the semiconductor substrate 134, such as over the interconnect structure. The contact pads 136 may include an electrically conductive material, such as a metal, for example aluminum or aluminum-copper. A passivation layer 138 is disposed on the contact pads 136 and over the interconnect structure. The passivation layer 138 may include one or more dielectric layers, such as silicon oxide layers, silicon nitride layers, silicon oxynitride layers, or a combination thereof. A dielectric layer 140 is disposed on the passivation layer 138. The dielectric layer 140 may include any suitable dielectric material. In some embodiments, the dielectric layer 140 is made of or includes a polymer, such as polyimide, polybenzoxazole (PBO), benzocyclobutene (BCB), or the like. The term “polymer” can represent thermosetting polymers, thermoplastic polymers, or any mixtures thereof. Another dielectric layer 142 is disposed on the dielectric layer 140. The dielectric layer 142 may include any suitable dielectric material. In some embodiments, the dielectric layer 142 is made of or includes a polymer, such as polyimide, PBO, BCB, or the like. One or more conductive features 144 are disposed in the dielectric layer 142. In some embodiments, although not shown, the conductive features 144 extend through the dielectric layer 140 and are in electrical contact with the contact pads 136. The conductive feature 144 may include an electrically conductive material, such as a metal, for example copper. In some embodiments, the top surfaces of the conductive features 144 and the top surface of the dielectric layer 142 are substantially coplanar, as shown in FIG. 2.

In some embodiments, after placing the semiconductor die 130 on the buffer layer 110, a curing process is performed to cure the DAF 132. The curing process may be a thermal process or a UV process. The curing of the DAF 132 adheres the semiconductor die 130 to the buffer layer 110.

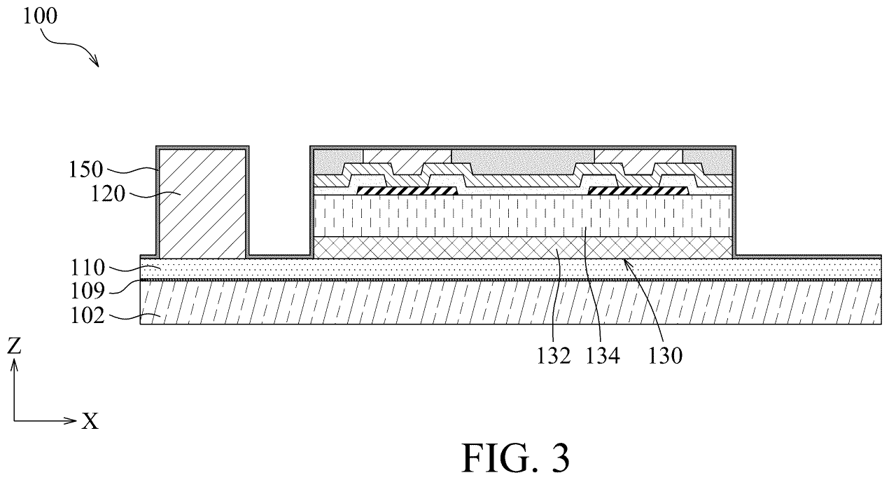

As shown in FIG. 3, a stress relief layer 150 is deposited over the buffer layer 110, around the conductive feature 120, and around the semiconductor die 130. The stress relief layer 150 may be deposited by any suitable process, such as CVD, ALD, PECVD, or the like. In some embodiments, the stress relief layer 150 has a CTE ranging from about 2.5 to about 9. In some embodiments, the stress relief layer 150 includes Si, C, O, N, or combinations thereof. For example, the stress relief layer 150 may be made of SiOₓ, where x is an integer or non-integer. The element ratio of silicon to oxygen may be 1:1.3-2, and the stress relief layer 150 has a CTE ranging from about 5.5 to about 7.5. In some embodiments, the stress relief layer 150 may be made of SiOCN having a CTE ranging from about 3 to about 6, and the element ratio of silicon to oxygen to carbon to nitrogen may be 1:1:1:1. In some embodiments, the stress relief layer 150 may be made of SiOₓN_{y}, where x and y are integers or non-integers. The element ratio of silicon to oxygen to nitrogen may be 1:0.67-0.9:1, and the stress relief layer 150 has a CTE ranging from about 2.5 to about 3.5. In some embodiments, the stress relief layer 150 may be made of SiₓN_{y}, where x and y are integers or non-integers. The element ratio of silicon to nitrogen may be 1:1.11-1.33, and the stress relief layer 150 has a CTE ranging from about 5 to about 9.

The stress relief layer 150 can reduce warpage of the packaging structure 100 after the subsequent molding formation. With the reduced warpage, tolerance of warpage of a semiconductor die to be formed over the semiconductor die 130 will be increased, and process window will be increased (increase package on wafer (PoW) joint yield). For example, in some embodiments, the semiconductor die 130 is an InFO package, and the semiconductor die to be formed over the InFO package is a dynamic random access memory (DRAM) package. If the InFO package has a smile-shaped warpage and the DRAM package has a frown-shaped warpage, conductive bumps on the two sides ac squeezed when joining the DRAM package with the InFO package, which could lead to bad yield. If the InFO package and the DRAM package both have smile-shaped warpages but are not matching, some conductive bumps are not in contact with solders on the InFO package when joining the DRAM package with the InFO package, which could lead to open circuit and bad yield. Thus, by controlling the warpage of the InFO package, tolerance of the warpage of the DRAM package is increased, and PoW joint yield is also increased.

The warpage of the packaging structure 100 is a result of mismatching CTE. For example, the subsequently formed molding material 152 (FIG. 3) has a CTE greater than 40, while the carrier 102 has a CTE ranging from about 5.1 to about 8.8. In some embodiments, after a curing process, which may be a thermal curing process, to cure the molding material 152, the molding material 152 is under a tensile stress due to the high CTE, while the carrier 102 is under compressive stress due to the low CTE. As a result, the carrier 102 has a smile-shaped warpage. A grinding process may be performed after the curing process to remove portions of the molding material 152 formed on the dielectric layer 142 (FIG. 2), and the grinding process releases the tensile stress on the molding material 152. As a result, the carrier 102 has a frown-shaped warpage. Warpage is a function of film stress, which is a function of effective CTE of the components of the packaging structure 100. By using the stress relief layer 150, which has a low CTE, the effective CTE of the components of the packaging structure 100 is reduced, which in turn reduces warpage of the carrier 102 after the curing process. With a reduced warpage after the curing process, the releasing of the stress of the carrier 102 after the grinding process is minimized, which in turn reduces the warpage after the grinding process. In some embodiments, the dielectric constant of the stress relief layer 150 is different from the dielectric constant of the molding material. For example, the dielectric constant of the stress relief layer 150 is greater than the dielectric constant of the molding material 152.

In some embodiments, the stress relief layer 150 has a thickness ranging from about 200 angstroms to about 4000 angstroms. If the thickness of the stress relief layer 150 is less than about 200 angstroms, the effective CTE of the components of the packaging structure 100 cannot be reduced, and the warpage of the carrier 102 cannot be reduced. On the other hand, if the thickness of the stress relief layer 150 is greater than about 4000 angstroms, there may be a waste of material and an overly thick resulting device. In some embodiments, the stress relief layer 150 is a conformal layer and formed by a conformal process, such as ALD. The term “conformal” may be used herein for ease of description upon a layer having substantial same thickness over various regions.

In some embodiments, the stress relief layer 150 is a continuous layer extending across the carrier 102 and surrounding components disposed over the carrier 102. In some embodiments, multiple conductive features 120 and multiple semiconductor dies 130 are disposed over the carrier 102, and the stress relief layer 150 surrounds the side surfaces and the top surface of each of the multiple conductive features 120 and semiconductor dies 130.

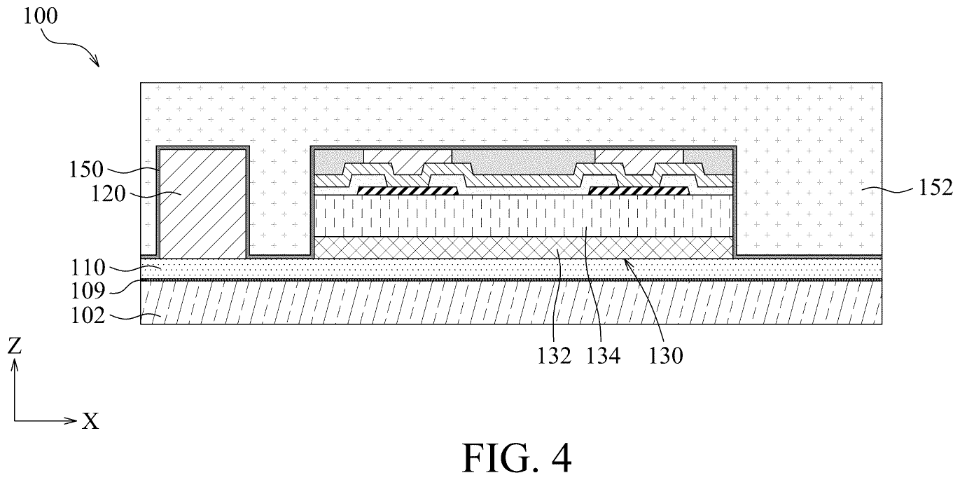

As shown in FIG. 4, the molding material 152 (or molding compound) is formed to encapsulate the conductive feature 120 and the semiconductor die 130. In some embodiments, the molding material 152 includes a polymer-based material. The polymer-based material can include, for example, plastic materials, epoxy resin, polyimide, polyethylene terephthalate (PET), polyvinyl chloride (PVC), polymethylmethacrylate (PMMA), polymer components doped with fillers including fiber, clay, ceramic, inorganic particles, or any combinations thereof. In some embodiments, the molding material is a polymer. Next, the molding material 152 is cured by a curing process, in some embodiments. The curing process may include heating the molding material 152 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process. Alternatively, the molding material 152 may be cured using other methods.

After the curing process, the packaging structure 100 is not substantially warped as a result of having the stress relief layer 150. Without the stress relief layer 150, the carrier 102 may have a smile-shaped warpage, as described above.

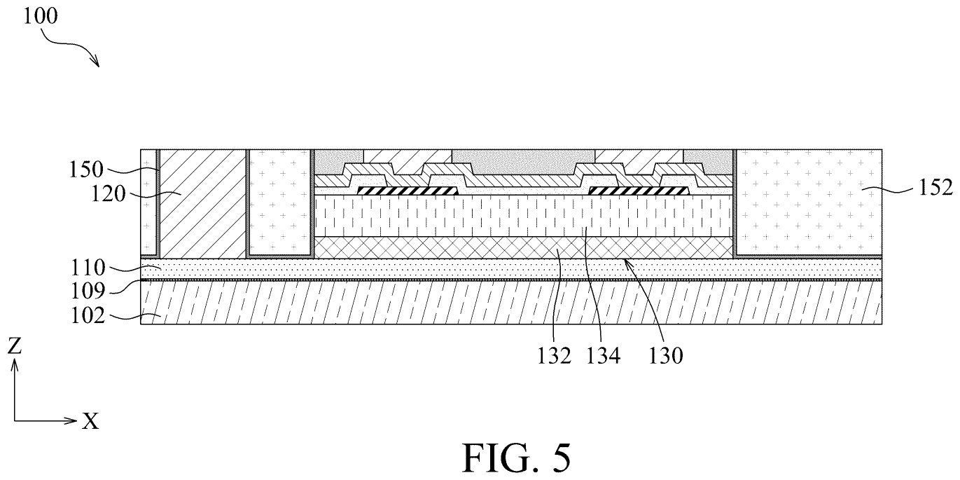

As shown in FIG. 5, a grinding process or a planarization process is performed to remove the portion of the molding material 152 disposed over the semiconductor die 130 and the conductive feature 120. In some embodiments, the grinding process also removes portions of the stress relief layer 150 disposed on the semiconductor die 130 and the conductive feature 120. As a result, in some embodiments, the top surfaces of the semiconductor die 130, the conductive feature 120, and the molding material 152 are substantially coplanar. As shown in FIG. 5, after the grinding process, the stress relief layer 150 is disposed on side surfaces of the conductive feature 120 and the side surfaces of the semiconductor die 130. Because the warpage of the carrier 102 after the curing process is reduced, the grinding process does not cause a release of stress. As a result, the frown-shaped warpage after the grinding process is also reduced. In some embodiments, the molding material 152 has a height along the Z direction ranging from about 500 μm to about 800 μm. In some embodiments, the planarization process may cause the top surface of the molding material 152 to be at a level below the top surface of the conductive feature 120 due to loading effect. In some embodiments, the stress relief layer 150 is made of an inorganic material, the molding material 152 is made of an organic material, and the molding material 152 may be slightly peeled off from the stress relief layer 150 after the planarization process. In other words, a top portion of the molding material 152 may be separated from a top portion of the stress relief layer 150. In some embodiments, the top portion of the molding material 152 has a height less than about 50 percent of the height of the molding material 152 along the Z direction, such as less than about 10 percent of the height of the molding material 152.

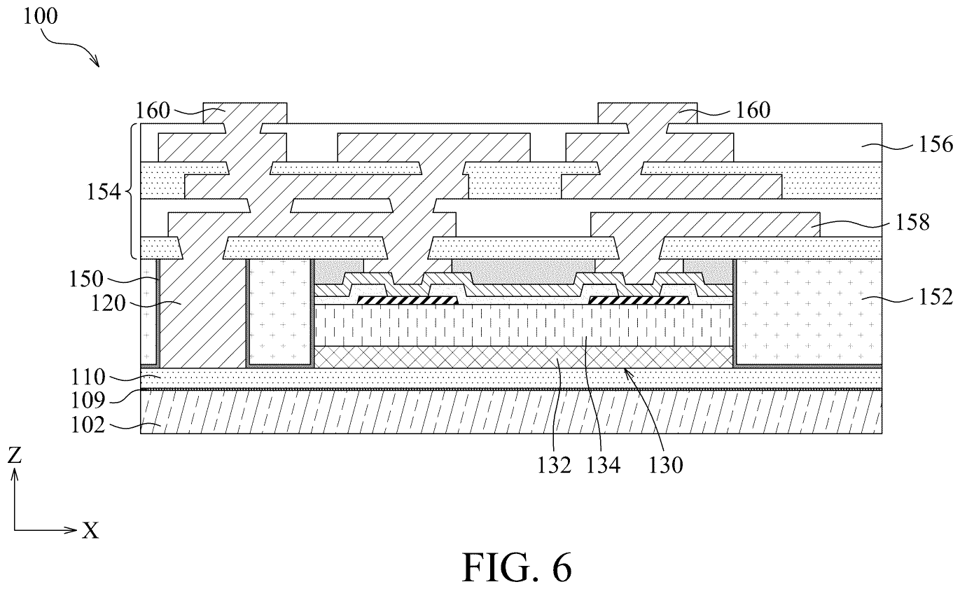

As shown in FIG. 6, a redistribution layer (RDL) 154 is formed on the molding material 152, the conductive feature 120, and the semiconductor die 130. In some embodiments, the RDL 154 is a structure including a plurality of dielectric layers 156 and a plurality of conductive features 158 embedded in the plurality of dielectric layers, as shown in FIG. 6. The dielectric layer 156 includes any suitable dielectric material, such as silicon nitride, silicon oxide, or the like, or a polymer, such as PBO, polyimide, or the like. The dielectric layer 156 may be formed by any suitable method, such as CVD, ALD, PECVD, FCVD, or other applicable deposition methods. In some embodiments, a curing process may be performed after the deposition of the dielectric layer 156. The curing process may be a thermal process. The conductive features 158 may include an electrically conductive material, such as a metal. In some embodiments, the conductive features 158 are formed by a plating process, which includes depositing a metal seed layer (not shown), forming and patterning a photo resist (not shown) over the metal seed layer, and plating a metallic material such as copper and/or aluminum over the metal seed layer. The metal seed layer and the plated metallic material may be formed of the same material or different materials. The patterned photo resist is then removed, followed by etching the portions of the metal seed layer previously covered by the patterned photo resist. The conductive features 158 may be electrically connected to the conductive feature 120 and the semiconductor die 130.

In some embodiments, one or more under-bump metallurgies (UBMs) 160 are formed on top of the RDL 154, as shown in FIG. 6. The UBMs 160 may be formed of an electrically conductive material, such as nickel, copper, titanium, or multi-layers thereof. In accordance with some exemplary embodiments, the UBMs 160 include a titanium layer and a copper layer over the titanium layer.

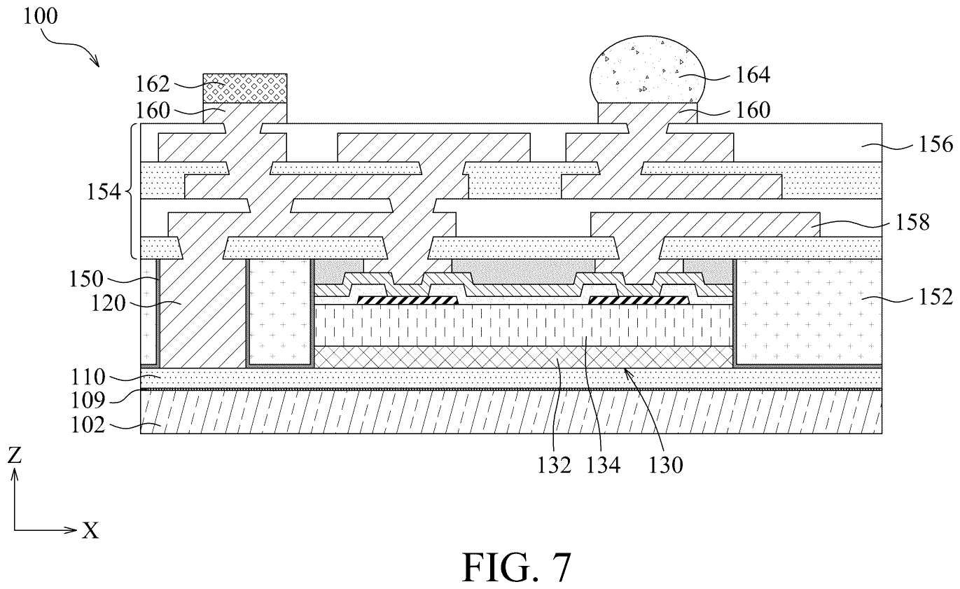

As shown in FIG. 7, an integrated passive device (IPD) 162 and a connector 164 are electrically connected to the UMBs 160. The IPD 162 may be a capacitor, a resistor, an inductor or the like, or a combination thereof. The connector 164 may be referred to as a conductive terminal. In some embodiments, the connector 164 is, for example, a solder ball or a ball grid array (BGA) ball. In some embodiments, the material of the connector 164 includes copper, aluminum, lead-free alloys (e.g., gold, tin, silver, aluminum, or copper alloys) or lead alloys (e.g., lead-tin alloys).

The processes to form the RDL 154 may further cause the packaging structure 100 to be under stress due to the thermal curing processes. Because the warpage of the packaging structure 100 after the grinding process is reduced, any warpage caused by the thermal curing processes during the formation of the RDL 154 may also be reduced.

Subsequent processes may include removing the carrier 102, bonding the semiconductor die 130 to a semiconductor die to form a three-dimensional device, and separating the three-dimensional devices.

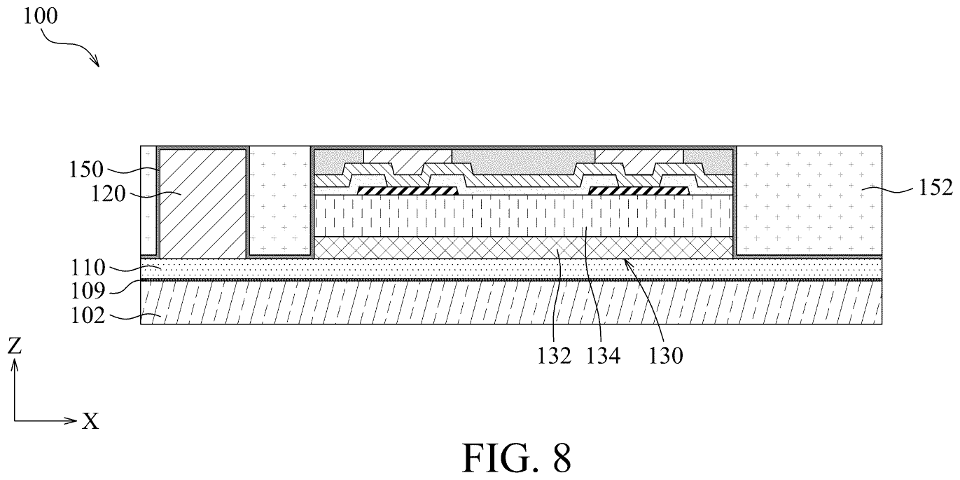

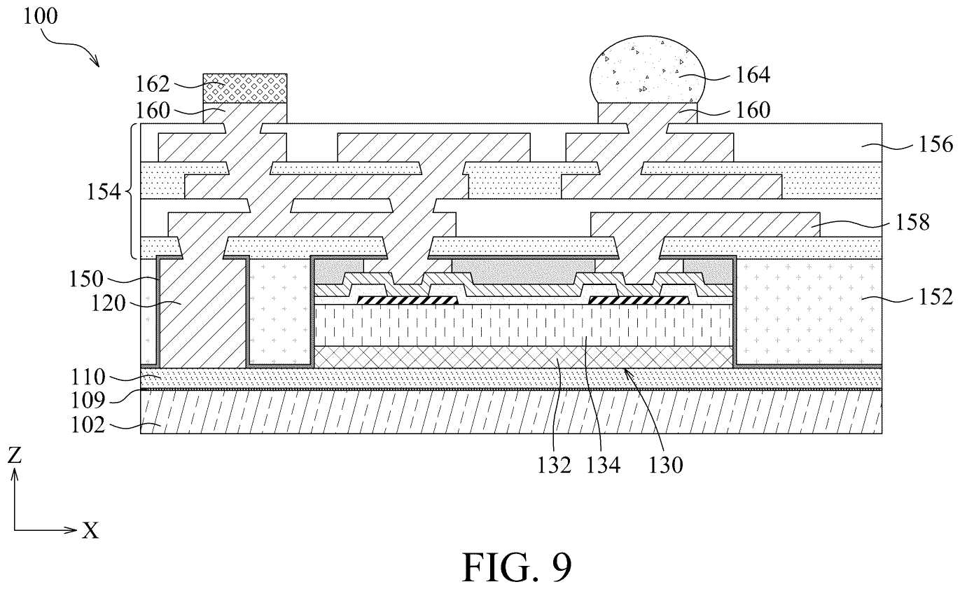

FIGS. 8 and 9 are side views of various stages of manufacturing the packaging structure 100, in accordance with alternative embodiments. As shown in FIG. 8, in some embodiments, the grinding process or the planarization process does not remove the portions of the stress relief layer 150 disposed on the conductive feature 120 and the semiconductor die 130. The portions of the stress relief layer 150 not removed by the grinding or planarization process may further reduce the warpage due to its low CTE. In some embodiments, the top surface of the stress relief layer 150 and the top surface of the molding material 152 are substantially coplanar, as shown in FIG. 8. Furthermore, the portions of the stress relief layer 150 disposed on the conductive feature 120 and the semiconductor die 130 may function as an etch stop layer during the formation of the conductive features 158, as shown in FIG. 9. The RDL 154 is formed over the stress relief layer 150 and the molding material 152, and the UBMs 160, the IPD 162, and the connector 164 are formed over the RDL 154, as shown in FIG. 9.

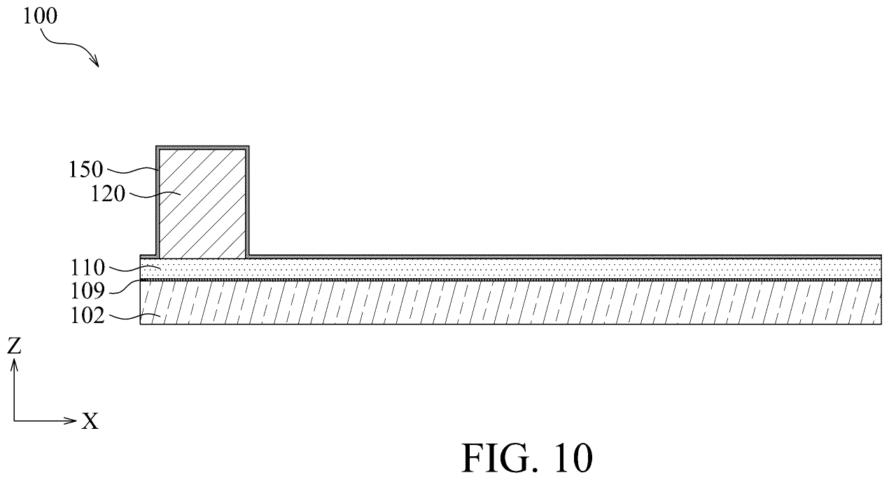

FIGS. 10, 11, 12, and 13 are side views of various stages of manufacturing the packaging structure 100, in accordance with alternative embodiments. As shown in FIG. 10, in some embodiments, the stress relief layer 150 is deposited after the formation of the conductive feature 120 but before attaching the semiconductor die 130. As described in FIG. 2, a curing process, such as a thermal process, may be performed after placing the semiconductor die 130 on the buffer layer 110. The mismatch CTE of the carrier 102 and the components formed over the buffer layer 110 may cause the carrier 102 to warp. Thus, by forming the stress relief layer 150 prior to placing the semiconductor die 130 on the buffer layer 110, warpage of the carrier 102 is reduced.

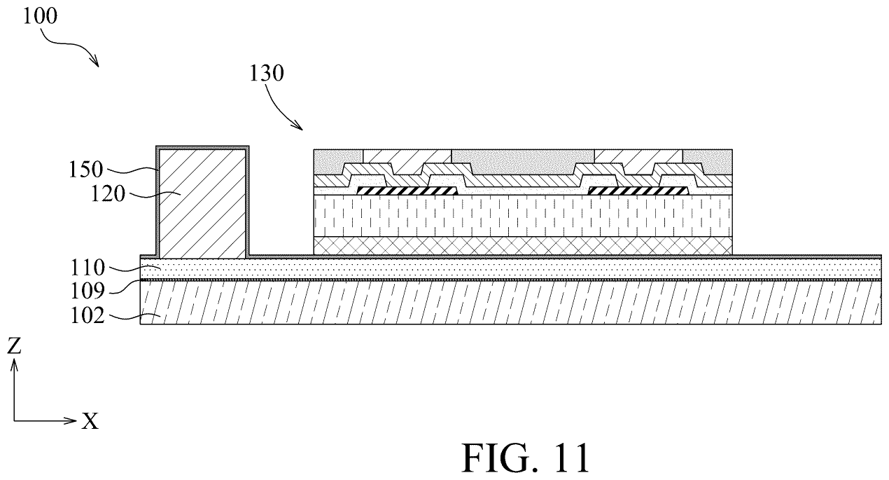

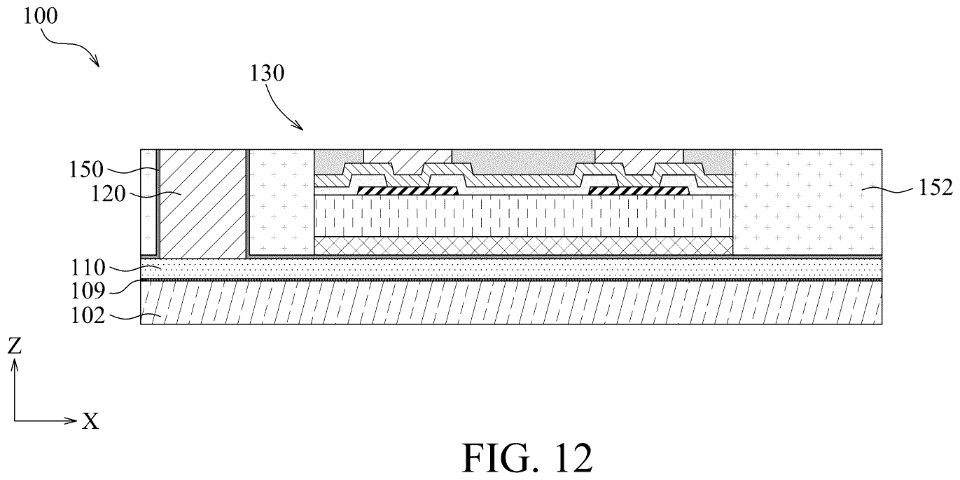

Next, as shown in FIG. 11, the semiconductor die 130 is placed on the stress relief layer 150, and the curing process is performed. The curing process may be a thermal process. The carrier 102 is not substantially warped as a result of the thermal process due to the presence of the stress relief layer 150. The molding material 152 is then formed over the stress relief layer 150, the conductive feature 120, and the semiconductor die 130, as shown in FIG. 12. As described above, the thermal curing process to cure the molding material 152 does not substantially cause a warpage of the packaging structure 100 due to the presence of the stress relief layer 150.

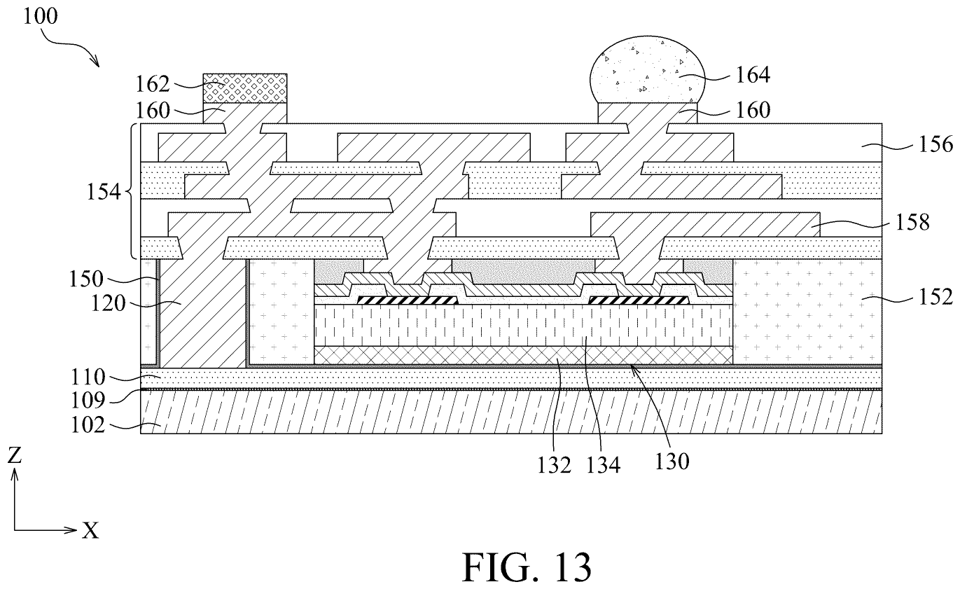

Next, as shown in FIG. 13, the RDL 154, the UBMs 160, the IPD 162, and the connector 164 are formed over the molding material 152, the conductive feature 120, and the semiconductor die 130. In some embodiments, the grinding process may remove the portion of the stress relief layer 150 disposed on the conductive feature 120, as shown in FIG. 13. Alternatively, the grinding process does not remove the portion of the stress relief layer 150 disposed on the conductive feature 120.

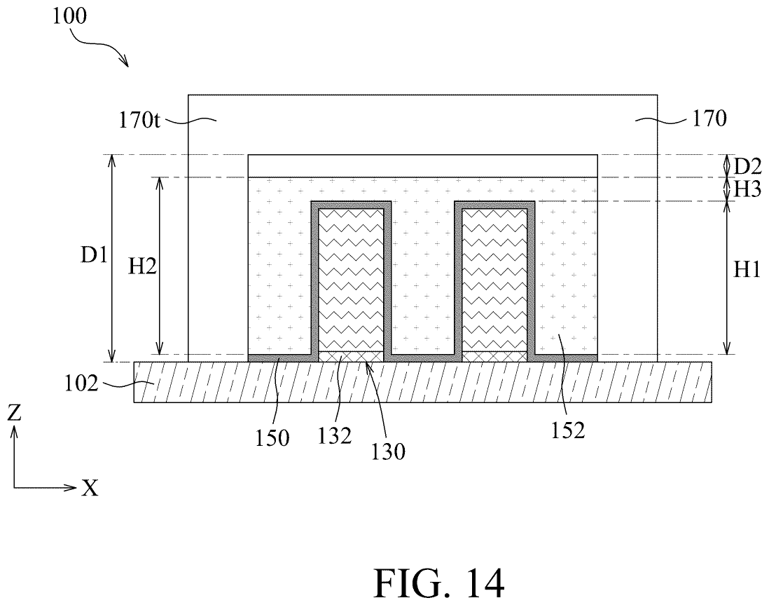

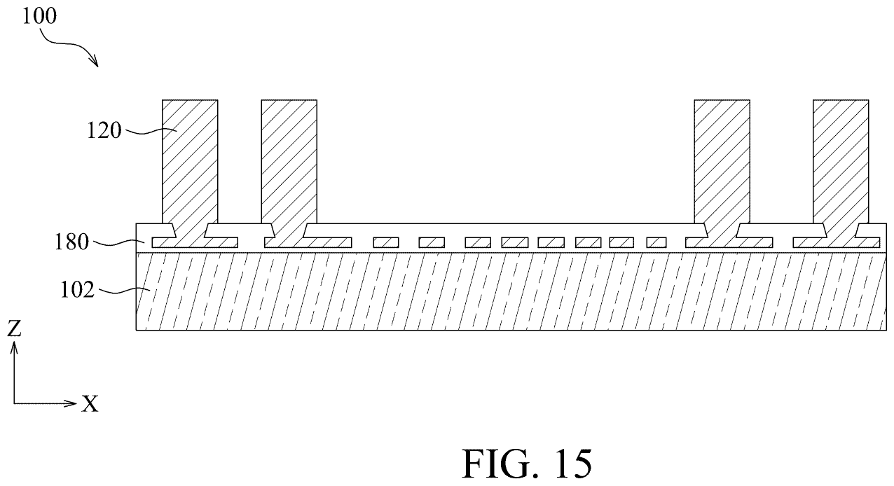

FIG. 14 is a side view of one of various stages of manufacturing the packaging structure 100, in accordance with some embodiments. The conductive feature 120, the buffer layer 110, the adhesive layer 109, and the details of the semiconductor die 130 are omitted in FIGS. 14 and 15 for clarity. As shown in FIG. 14, in some embodiments, the semiconductor die 130 is attached to the carrier 102 (or the buffer layer 110) by the DAF 132. The stress relief layer 150 is disposed over the carrier 102 and around the semiconductor die 130. In some embodiments, in order to form the molding material 152, a mold chase 170 is first disposed over the carrier 102 and the semiconductor die 130. In some embodiments, the mold chase 170 is in a predetermined shape or configuration. The mold chase 170 includes any suitable material, such as steel or the like. In some embodiments, a release film is disposed on a surface of the mold chase 170 facing the carrier 102. Next, the molding material 152 is injected through an opening (not shown) in the mold chase 170, as shown in FIG. 14.

In some embodiments, the semiconductor die 130 has a height H1 along the Z direction, and the molding material 152 has a height H2 along the Z direction. The height H2 may be substantially greater than the height H1. In some embodiments, the height H1 ranges from about 500 μm to about 800 μm, and the height H2 ranges from about 550 μm to about 850 μm. In some embodiments, the portion of the molding material 152 disposed over the semiconductor die 130 has a height H3 ranging from about 30 μm to about 100 μm. In some embodiments, the height H2 is greater than the height H1 is to ensure that the sides of the semiconductor dies 130 are not exposed. In some embodiments, the mold chase 170 has a top portion 170t that is a distance D1 from the carrier 102 (or the buffer layer 110). In some embodiments, the distance D1 ranges from about 600 μm to about 900 μm. The distance D1 is greater than the height H2 of the molding material 152. In some embodiments, a distance D2 is between the top portion 170t of the mold chase 170 and the molding material 152. The distance D2 may range from about 10 μm to about 100 μm._ After injecting the molding material 152, the mold chase 170 is removed, and subsequent processes described in FIGS. 4-7 may be performed.

FIGS. 15, 16, 17, 18, and 19 are side views of various stages of manufacturing the packaging structure 100, in accordance with alternative embodiments. As shown in FIG. 15, an RDL 180 is formed over the carrier 102. The RDL 180 may be a structure including a plurality of dielectric layers and a plurality of conductive features embedded in the plurality of dielectric layers, as shown in FIG. 15. The dielectric layer includes any suitable dielectric material, such as silicon nitride, silicon oxide, or the like, or a polymer, such as PBO, polyimide, or the like. The dielectric layer may be formed by any suitable method, such as CVD, ALD, PECVD, FCVD, or other applicable deposition methods. The conductive features may include an electrically conductive material, such as a metal. In some embodiments, the conductive features are formed by a plating process, which includes depositing a metal seed layer (not shown), forming and patterning a photo resist (not shown) over the metal seed layer, and plating a metallic material such as copper and/or aluminum over the metal seed layer. The metal seed layer and the plated metallic material may be formed of the same material or different materials. The patterned photo resist is then removed, followed by etching the portions of the metal seed layer previously covered by the patterned photo resist. In some embodiments, the adhesion layer 109 (FIG. 1) may be formed between the carrier 102 and the RDL 180.

In some embodiments, a plurality of conductive features 120 are formed on the RDL 180, as shown in FIG. 15. Each conductive feature 120 is electrically connected to a corresponding conductive feature in the RDL 180.

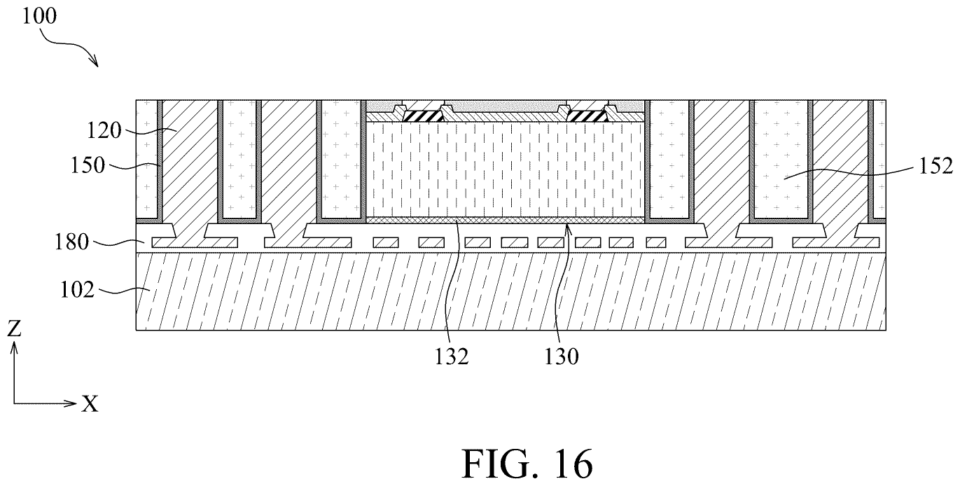

As shown in FIG. 16, the semiconductor die 130 is attached to the RDL 180 by the DAF 132. In some embodiments, the stress relief layer 150 is deposited after the attachment of the semiconductor die 130, as shown in FIG. 16. For example, the stress relief layer 150 may be deposited on the RDL 180 and surrounding the conductive features 120 and the semiconductor die 130. In some embodiments, the stress relief layer 150 is deposited before the attachment of the semiconductor die 130. For example, the stress relief layer 150 may be deposited on the RDL 180 and surrounding the conductive features 120, and the semiconductor die 130 is then placed on the stress relief layer 150. The molding material 152 is then formed on the stress relief layer 150. The curing process may be performed to cure the molding material 152, and the curing process may be a thermal curing process. With the stress relief layer 150, the effective CTE of the components of the packaging structure 100 is reduced, which in turn reduces warpage of the carrier 102 after the curing process.

Next, as shown in FIG. 16, the grinding process or planarization process is performed to remove portions of the molding material 152 formed on the conductive features 120 and the semiconductor die 130. In some embodiments, the grinding process also removes portions of the stress relief layer 150 disposed on the conductive features 120 and the semiconductor die 130, and the top surfaces of the conductive features 120 and the semiconductor die 130 are exposed, as shown in FIG. 16. Thus, in some embodiments, the top surfaces of the conductive features 120, the semiconductor die 130, and the molding material 152 are substantially coplanar. In some embodiments, the grinding process does not remove the portions of the stress relief layer 150 disposed on the conductive features 120 and the semiconductor die 130, and top surfaces of the stress relief layer 150 and the molding material 152 are substantially coplanar. With a reduced warpage after the curing process, the releasing of the stress of the carrier 102 after the grinding process is also minimized, which in turn reduces the warpage after the grinding process.

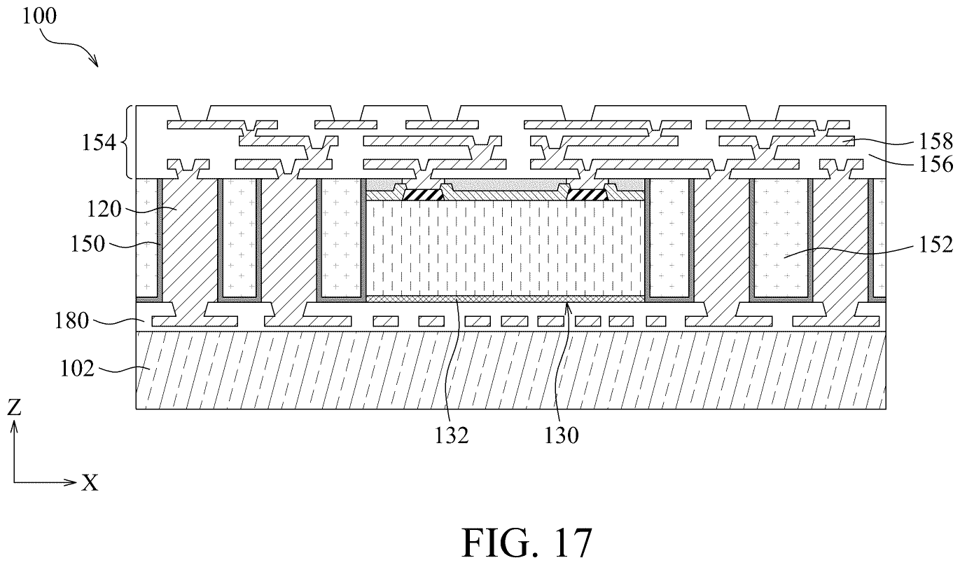

As shown in FIG. 17, the RDL 154 is formed over the semiconductor die 130 and the conductive features 120. The conductive features 158 in the RDL 154 are electrically connected to the semiconductor die 130 and the conductive features 120. As described above, the processes to form the dielectric layers 156 of the RDL 154 may include thermal curing processes. Warpage of the packaging structure 100 caused by the thermal curing processes may be minimized due to the presence of the stress relief layer 150 and that the warpage after the grinding process is reduced.

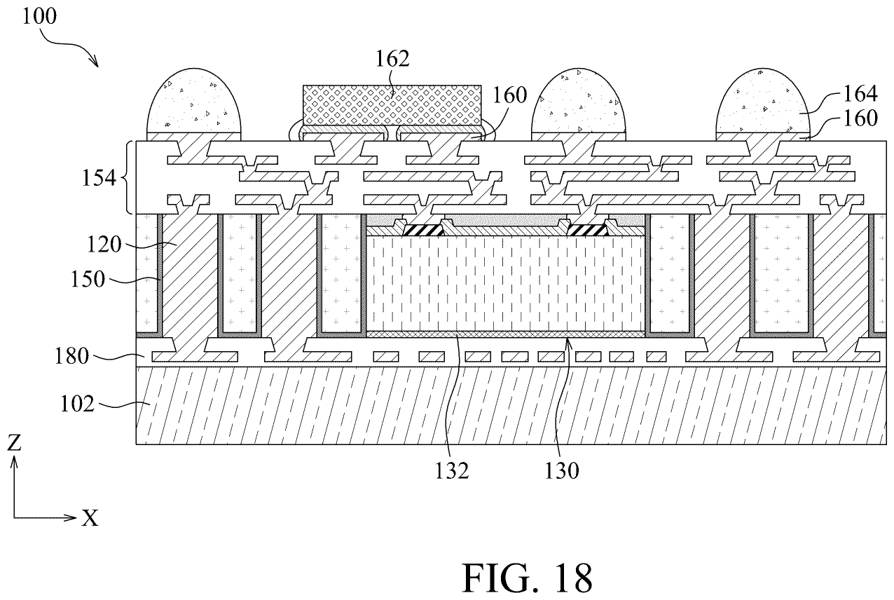

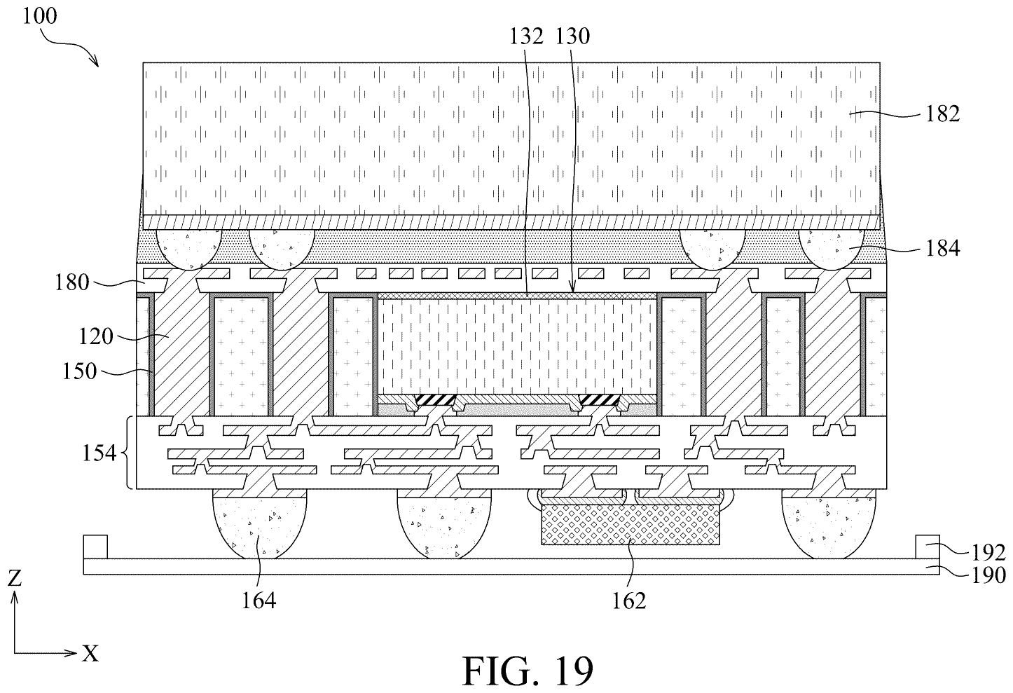

As shown in FIG. 18, the UBMs 160, the IPD 162, and the connectors 164 are formed over the RDL 154. Next, as shown in FIG. 19, the packaging structure 100 is flipped over and placed on a tape 190, which is attached to a frame 192. In accordance with some embodiments of the present disclosure, the connectors 164 are in contact with the tape 190. Next, a light is projected on the adhesion layer (not shown) disposed between the carrier 102 and the RDL 180, and the light penetrates through the transparent carrier 102. In accordance with some exemplary embodiments of the present disclosure, the light is a laser beam. As a result of the light-exposure (such as the laser scanning), the carrier 102 may be lifted off from the adhesion layer, and hence the packaging structure 100 is de-bonded (demounted) from the carrier 102.

As shown in FIG. 19, a semiconductor die 182 is electrically attached to the RDL 180 of the packaging structure 100. In some embodiments, the semiconductor die 182 is a DRAM die, and the semiconductor die 182 is attached to the RDL 180 by a plurality of connectors 184. The connectors 184 may include the same material as the connectors 164 and may be formed by the same process as the connectors 164. As described above, due to the reduced warpage of the packaging structure 100 (prior to attaching to the semiconductor die 182), the tolerance of DRAM die warpage is increased, and the process window is increased (PoW joint yield is increased).

The present disclosure in various embodiments provides a packaging structure 100 including a stress relief layer 150. The stress relief layer 150 may be formed before attaching a semiconductor die 130 or after attaching the semiconductor die 130. Some embodiments may achieve advantages. For example, the stress relief layer 150 has a low CTE, which lowers the effective CTE of the packaging structure 100. Lowered effective CTE can lead to lowered film stress, which leads to reduced warpage. The packaging structure 100 with the reduced warpage can lead to increased tolerance of warpage of a semiconductor die 182 to be attached to the packaging structure 100. Furthermore, increased PoW joint yield may be achieved.

An embodiment is a semiconductor device structure. The structure includes a through via, a first semiconductor die disposed adjacent the through via, a stress relief layer disposed on side surfaces of the through via and side surfaces of the first semiconductor die, and a molding material disposed on the stress relief layer and between the through via and the first semiconductor die. Top surfaces of the through via, the semiconductor die, and the molding material are substantially coplanar.

Another embodiment is a semiconductor device structure. The structure includes a semiconductor die, a molding material disposed around the semiconductor die, and a through via. The molding material is disposed between the semiconductor die and the through via. The structure further includes a stress relief layer surrounding side surfaces and a top surface of the through via. The stress relief layer surrounds side surfaces and a top surface of the semiconductor die, and top surfaces of the molding material and the stress relief layer are substantially coplanar.

A further embodiment is a method. The method includes forming a through via over a carrier, placing a semiconductor die over the carrier, and depositing a stress relief layer around the through via and over the carrier. The stress relief layer is a continuous and conformal layer. The method further includes forming a molding material over the stress relief layer, the through via, and the semiconductor die. The molding material is formed between the through via and the semiconductor die. The method further includes performing a grinding process to remove a portion of the molding material formed over the through via and the semiconductor die and forming a redistribution layer over the through via, the semiconductor die, and the stress relief layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A packaging structure, comprising:
a through via;
a first semiconductor die disposed adjacent the through via;
a stress relief layer disposed on side surfaces of the through via and side surfaces of the first semiconductor die; and
a molding material disposed on the stress relief layer and between the through via and the first semiconductor die, wherein top surfaces of the through via, the first semiconductor die, and the molding material are substantially coplanar.

2. The packaging structure of claim 1, wherein the stress relief layer has a thickness ranging from about 200 angstroms to about 4000 angstroms.

3. The packaging structure of claim 1, wherein the stress relief layer comprises silicon and oxygen.

4. The packaging structure of claim 3, wherein the stress relief layer further comprises nitrogen and/or carbon.

5. The packaging structure of claim 1, wherein the stress relief layer comprises silicon and nitrogen.

6. The packaging structure of claim 1, further comprising a first redistribution layer disposed on and in contact with top surfaces of the molding material, the through via, and the first semiconductor die.

7. The packaging structure of claim 6, further comprising a second redistribution layer disposed under the through via, the molding material, and the first semiconductor die, wherein the stress relief layer comprises a horizontal portion overlaid with the first and second redistribution layers.

8. The packaging structure of claim 7, further comprising a second semiconductor die disposed under the second redistribution layer.

9. The packaging structure of claim 1, wherein the stress relief layer is covered by a bottom of the molding material.

10. A packaging structure, comprising:
a semiconductor die;
a molding material disposed around the semiconductor die;
a through via, wherein the molding material is disposed between the semiconductor die and the through via; and
a stress relief layer surrounding side surfaces and a top surface of the TIV, wherein the stress relief layer surrounds side surfaces and a top surface of the semiconductor die, and top surfaces of the molding material and the stress relief layer are substantially coplanar.

11. The packaging structure of claim 10, further comprising a redistribution layer disposed on and in contact with the stress relief layer and the molding material.

12. The packaging structure of claim 11, wherein the redistribution layer comprises a first conductive feature extending through the stress relief layer and in contact with the through via.

13. The packaging structure of claim 12, wherein the redistribution layer further comprises a second conductive feature extending through the stress relief layer and in contact with the semiconductor die.

14. The packaging structure of claim 10, wherein the stress relief layer has a thickness ranging from about 200 angstroms to about 4000 angstroms.

15. The packaging structure of claim 10, wherein the stress relief layer comprises Si, C, O, N, or combinations thereof.

16. The packaging structure of claim 15, wherein the stress relief layer further comprises SiO, SiN, SiOCN, or SiON.

17. A method for forming a packaging structure, comprising:
forming a through via over a carrier;
placing a semiconductor die over the carrier;
depositing a stress relief layer around the through via and over the carrier, wherein the stress relief layer is a continuous and conformal layer;
forming a molding material over the stress relief layer, the through via, and the semiconductor die, wherein the molding material is formed between the through via and the semiconductor die;
performing a grinding process to remove a portion of the molding material formed over the through via and the semiconductor die; and
forming a redistribution layer over the through via, the semiconductor die, and the stress relief layer.

18. The method of claim 17, wherein the semiconductor die is placed on the stress relief layer.

19. The method of claim 17, wherein the stress relief layer surrounds side surfaces and a top surface of the semiconductor die.

20. The method of claim 17, wherein the carrier is a glass carrier.
